(19) United States
(12) Patent Application Publication
(10) Pub. No.: US 2024/0364082 A1
(43) Pub. Date: Oct. 31, 2024

(54) RADIATION-EMITTING SEMICONDUCTOR BODY, LASER DIODE AND LIGHT-EMITTING DIODE

(71) Applicant: ams-OSRAM International GmbH, Regensburg (DE)

(72) Inventors: Heng WANG, Eriskirch (DE); Stefan ILLEK, Donaustauf (DE)

(73) Assignee: ams-OSRAM International GmbH, Regensburg (DE)

(21) Appl. No.: 18/292,062

(22) PCT Filed: Jul. 21, 2022
(86) PCT No.: PCT/EP2022/070504

§ 371 Date: Jan. 25, 2024

(30) Foreign Application Priority Data
Jul. 28, 2021 (DE) 10 2021 119 596.9

(51) Int. Cl. H01S 5/30; H01L 33/06; H01L 33/14; H01L 33/30; H01S 5/343

(52) U.S. Cl. CPC H01S 5/3077; H01L 33/06; H01L 33/145; H01L 33/305; H01S 5/34326; H01S 5/3436

(57) ABSTRACT

The invention relates to a radiation-emitting semiconductor body, having a first semiconductor region of a first doping type, which has a first material composition, a second semiconductor region of a second doping type, which has a second material composition, an active region, which is located between the first semiconductor region and the second semiconductor region, and a first intermediate region, which is located between the first semiconductor region and the active region, wherein the active region includes a plurality of quantum well layers and a plurality of barrier layers, which are arranged alternatingly one above the other, the barrier layers have a third material composition, the first intermediate region includes at least one first blocking layer and at least one first intermediate layer, and the first blocking layer has a fourth material composition and the first intermediate layer has a fifth material composition. The invention also relates to a laser diode and to a light-emitting diode.

### CROSS-REFERENCE TO RELATED APPLICATIONS

The present application is a national stage entry from International Application No. PCT/EP2022/070504, filed on Jul. 21, 2022, published as International Publication No. WO 2023/006577 A1 on Feb. 2, 2023, and claims priority to German Patent Application No. 10 2021 119 596.9,filed Jul. 28, 2021, the disclosures of all of which are hereby incorporated by reference in their entireties.

### FIELD

A radiation emitting semiconductor body is specified. A laser diode and a light emitting diode are also specified.

### BACKGROUND

An object to be solved is to specify a radiation emitting semiconductor body which can be operated particularly efficiently. In addition, a laser diode and a light emitting diode with such a radiation emitting semiconductor body are to be specified.

### SUMMARY

The radiation emitting semiconductor body is based, for example, on a III-V compound semiconductor material. The semiconductor compound material is, for example, a phosphide compound semiconductor material.

The radiation emitting semiconductor body is configured to emit electromagnetic radiation. The electromagnetic radiation emitted by the radiation emitting semiconductor body is, for example, ultraviolet radiation, near-ultraviolet radiation, visible light, near-infrared radiation or infrared radiation.

The radiation emitting semiconductor body comprises, for example, a main extension plane. A vertical direction extends perpendicular to the main extension plane and lateral directions extend parallel to the main extension plane.

According to at least one embodiment, the radiation emitting semiconductor body comprises a first semiconductor region of a first doping type comprising a first material composition.

The first semiconductor region comprises, for example, a first semiconductor layer of a first semiconductor layer sequence.

The first semiconductor region, in particular the first semiconductor layer sequence, comprises, for example, a first dopant. By means of the first dopant, the first semiconductor region is, for example, p-doped and thus formed p-conducting. In this case, the first doping type is a p-type.

Alternatively, the first semiconductor region is, for example, n-doped by means of the first dopant and is therefore n-conducting. In this case, the first doping type is an n-type.

According to at least one embodiment, the radiation emitting semiconductor body comprises a second semiconductor region of a second doping type comprising a second material composition. The second semiconductor region comprises, for example, a second semiconductor layer of a second semiconductor layer sequence.

The second semiconductor region, in particular the second semiconductor layer sequence, comprises, for example, a second dopant. If the first semiconductor region is p-doped by means of the first dopant, the second semiconductor region is n-doped by means of the second dopant. In this case, the second doping type is an n-type.

If the first semiconductor region is n-doped by means of the first dopant, the second semiconductor region is p-doped by means of the second dopant. In this case, the second doping type is a p-type.

The first material composition and the second material composition are based, for example, on AlₓGa₁₋ₓP, where 0≤x≤1. In particular, the first material composition and the second material composition are based on InₓGa_{y}Al₁₋ₓP, where 0≤x≤1 and 0≤y≤1. For example, the first material composition is provided with the first dopant. Furthermore, the second material composition can be provided with the second dopant.

According to at least one embodiment, the radiation emitting semiconductor body comprises an active region arranged between the first semiconductor region and the second semiconductor region. The active region is configured, for example, to generate the electromagnetic radiation.

For example, the active region is in direct contact with the second semiconductor region, in particular the second semiconductor layer. The active region comprises, for example, a multiple quantum well structure.

According to at least one embodiment, the radiation emitting semiconductor body comprises a first intermediate region arranged between the first semiconductor region and the active region. The first intermediate region is, for example, in direct contact with the active region and the first semiconductor region, in particular the first semiconductor layer.

According to at least one embodiment of the radiation emitting semiconductor body, the active region comprises several quantum well layers and several barrier layers, which are arranged alternately above each other. The quantum well layers and the barrier layers are stacked above each other in vertical direction, for example. Directly adjacent quantum well layers and barrier layers are in direct contact with each other, for example.

According to at least one embodiment of the radiation emitting semiconductor body, the barrier layers comprise a third material composition. For example, the third material composition is based on InₓGa_{y}Al₁₋ₓP, where 0≤x≤1 and 0≤y≤1.

For example, a band gap of the quantum well layers and the barrier layers is predeterminable dependent on of an aluminum concentration in the quantum well layers and in the barrier layers.

For example, the barrier layers comprise a higher aluminum concentration than the aluminum concentration in the quantum well layers. This means that the quantum well layers comprise a smaller band gap than the barrier layers.

The quantum well layers and/or the barrier layers comprise, for example, a thickness in vertical direction of at least 2 nm and at most 10 nm. For example, the quantum well layers and the barrier layers comprise the same thickness.

Alternatively, the thicknesses of the quantum well layers and the barrier layers are different.

According to at least one embodiment of the radiation emitting semiconductor body, the first intermediate region comprises at least one first blocking layer and at least one first intermediate layer. The first blocking layer and the first intermediate layer are stacked above each other in vertical direction, for example, and are in direct contact with each other. The first blocking layer is in direct contact with the active region. Furthermore, the first intermediate layer is in direct contact with the first semiconductor region, in particular the first semiconductor layer.

For example, the first intermediate region comprises several first blocking layers and several first intermediate layers, which are arranged alternately above each other. The first blocking layers and the first intermediate layers are stacked above each other in vertical direction, for example. Directly adjacent first blocking layers and first intermediate layers are in direct contact with each other, for example.

For example, a number of the first blocking layers and the first intermediate layers are the same. An outer first blocking layer is in direct contact with the active region and an outer first intermediate layer is in direct contact with the first semiconductor region, in particular the first semiconductor layer.

According to at least one embodiment of the radiation emitting semiconductor body, the first blocking layer comprises a fourth material composition and the first intermediate layer comprises a fifth material composition.

For example, the fourth material composition and the fifth material composition are based on AlₓGa₁₋ₓP, where 0≤x≤1. In particular, the fourth material composition and the fifth material composition are based on InₓGa_{y}Al₁₋ₓP, where 0≤x≤1 and 0≤y≤1.

The first intermediate layer comprises, for example, an aluminum concentration that is greater than or less than an aluminum concentration of the barrier layers. The first blocking layer comprises, for example, an aluminum concentration that is greater than or less than an aluminum concentration of the first semiconductor region, in particular the first semiconductor layer.

A band gap is predeterminable dependent on an aluminum concentration. For example, a band gap of the first blocking layer is smaller or larger than a band gap of the first semiconductor region, in particular of the first semiconductor layer, by at most 5%, in particular by at most 10% or 30%. For example, a band gap of the first intermediate layer is smaller or larger than a band gap of the barrier layers by at most 5%, in particular by at most 10% or 30%.

According to at least one embodiment of the radiation emitting semiconductor body, the fourth material composition is the same as the first material composition.

According to at least one embodiment of the radiation emitting semiconductor body, the fifth material composition is the same as the third material composition.

The first intermediate layer comprises, for example, an aluminum concentration that is equal to an aluminum concentration of the barrier layers. The first blocking layer comprises, for example, an aluminum concentration that is equal to an aluminum concentration of the first semiconductor region, in particular the first semiconductor layer.

The first intermediate layer comprises, for example, a band gap that is equal to a band gap of the barrier layers. Furthermore, the first blocking layer comprises a band gap which is, for example, equal to a band gap of the first semiconductor region, in particular of the first semiconductor layer.

For example, the quantum well layers comprise a smaller aluminum concentration than the barrier layers. Furthermore, the first blocking layer comprises, for example, a higher aluminum concentration than an aluminum concentration of the barrier layers. Thus, for example, the first blocking layer comprises a higher aluminum concentration than the first intermediate layer.

Between the first blocking layer, which comprises a high aluminum concentration compared to the first intermediate layer, and the first intermediate layer, which comprises a low aluminum concentration compared to the first blocking layer, a defect density can be formed particularly high. In particular, a particularly large number of gallium vacancies can be arranged between the first blocking layer and the first intermediate layer.

In at least one embodiment, the radiation emitting semiconductor body comprises a semiconductor region of a first doping type comprising a first material composition, a second semiconductor region of a second doping type comprising a second material composition, an active region arranged between the first semiconductor region and the second semiconductor region, and a first intermediate region arranged between the first semiconductor region and the active region. The active region comprises a plurality of quantum well layers and a plurality of barrier layers arranged alternately above each other. The barrier layers comprise a third material composition. The first intermediate region comprises at least one first blocking layer and at least one first intermediate layer. The first blocking layer comprises a fourth material composition and the first intermediate layer comprises a fifth material composition.

An idea of the radiation emitting semiconductor body described herein is, among other things, to arrange the first intermediate region on the active region. The first intermediate region comprises a layer sequence which is advantageously configured to suppress diffusion of dopants in the direction of the active region.

Between the first blocking layer of the intermediate region, which comprises a high aluminum concentration compared to the first intermediate layer, and the first intermediate layer, which comprises a low aluminum concentration compared to the first blocking layer, a defect density can be greater than in the first semiconductor region and/or in the layers of the first intermediate region and the active region. In particular, more gallium vacancies can be arranged between the first blocking layer and the first intermediate layer than in the first semiconductor region and/or in the layers of the first intermediate region and the active region.

For example, the first semiconductor region includes the first dopant. Without the first intermediate region, the first dopant could diffuse from the first semiconductor region to the active region and thus reduce the efficiency of generating electromagnetic radiation in the active region. In the first intermediate region, where the first blocking layer and the first intermediate layer are adjacent to each other, the diffusion of the first dopant to the active region can be significantly reduced. As a result, the active region is advantageously free of the first dopant and the generation of electromagnetic radiation in the active region is particularly efficient.

In contrast to a semiconductor body in which only an undoped layer is arranged between a first semiconductor region and an active region, a first intermediate region described herein, which comprises a layer sequence, is advantageously formed to be particularly thin. For example, such a first intermediate region is at least one order of magnitude thinner than the undoped layer. Thus, the first semiconductor region is further advantageously arranged particularly close to the active region. This advantageously leads to improved charge carrier injection into the active region and to reduced charge carrier losses.

According to at least one embodiment of the radiation emitting semiconductor body, all material compositions are based on AlGaInP.

According to at least one embodiment of the radiation emitting semiconductor body, a second intermediate region is arranged between the second semiconductor region and the active region. The second intermediate region is, for example, in direct contact with the active region and the second semiconductor region, in particular the second semiconductor layer.

According to at least one embodiment of the radiation emitting semiconductor body, the second intermediate region comprises at least one second blocking layer and at least one second intermediate layer. The second blocking layer and the second intermediate layer are stacked above each other in vertical direction, for example, and are in direct contact with each other. The second blocking layer is in direct contact with the active region. Furthermore, the second intermediate layer is in direct contact with the second semiconductor region, in particular the second semiconductor layer.

For example, the second intermediate region comprises several second blocking layers and several second intermediate layers, which are arranged alternately above each other. The second blocking layers and the second intermediate layers are stacked above each other in vertical direction, for example. Directly adjacent second blocking layers and second intermediate layers are in direct contact with each other, for example.

For example, a number of the second blocking layers and the second intermediate layers are the same. An outer second blocking layer is in direct contact with the active region and an outer second intermediate layer is in direct contact with the second semiconductor region, in particular the second semiconductor layer.

According to at least one embodiment of the radiation emitting semiconductor body, the second blocking layer comprises a sixth material composition and the second intermediate layer comprises a seventh material composition.

For example, the sixth material composition and the seventh material composition are based on AlₓGa₁₋ₓP, where 0≤x≤1. In particular, the fourth material composition and the seventh material composition are based on InₓGa_{y}Al₁₋ₓP, where 0≤x≤1 and 0≤y≤1.

The second intermediate layer comprises, for example, an aluminum concentration that is greater than or less than an aluminum concentration of the barrier layers. The second blocking layer comprises, for example, an aluminum concentration that is greater than or less than an aluminum concentration of the second semiconductor region, in particular the second semiconductor layer.

For example, a band gap of the second blocking layer is smaller or larger than a band gap of the second semiconductor region, in particular the second semiconductor layer, by at most 5%, in particular by at most 10% or 30%. For example, a band gap of the second intermediate layer is smaller or larger than a band gap of the barrier layers by at most 5%, in particular by at most 10% or 30%.

According to at least one embodiment of the radiation emitting semiconductor body, the sixth material composition is the same as the second material composition, and/or the seventh material composition is the same as the third material composition.

The second intermediate layer comprises, for example, an aluminum concentration that is equal to an aluminum concentration of the barrier layers. The second blocking layer comprises, for example, an aluminum concentration that is equal to an aluminum concentration of the second semiconductor region, in particular the second semiconductor layer.

The second intermediate layer comprises, for example, a band gap that is equal to a band gap of the barrier layers. Furthermore, the second blocking layer comprises a band gap which is, for example, equal to a band gap of the second semiconductor region, in particular the second semiconductor layer.

According to at least one embodiment of the radiation emitting semiconductor body, the first semiconductor region comprises a first dopant.

For example, the first dopant diffuses from the first semiconductor region in direction of the active region. Diffusion of the first dopant is advantageously inhibited by the first intermediate region indicated herein.

For example, the first intermediate region comprises the first dopant. A concentration of the first dopant decreases, for example, in vertical direction in direction of the active region. For example, the concentration of the first dopant in the first intermediate region decreases disproportionately in the region where the first intermediate layer is consecutively applied to the first blocking layer.

The first intermediate region is, for example, at least partially free of the first dopant. Advantageously, a region of the first intermediate region that is arranged directly adjacent to the active region comprises no first dopant. This means that the diffusion of the first dopant to the active region is advantageously prevented.

According to at least one embodiment of the radiation emitting semiconductor body, the second semiconductor region comprises a second dopant.

For example, the second dopant diffuses from the second semiconductor region in the direction of the active region. Diffusion of the second dopant is advantageously inhibited by the second intermediate region indicated herein.

The second intermediate region is, for example, at least partially free of the second dopant. Advantageously, a region of the second intermediate region that is arranged directly adjacent to the active region comprises no second dopant. This means that diffusion of the second dopant to the active region is advantageously prevented.

In particular, the active region is free of the first dopant and/or the second dopant.

According to at least one embodiment of the radiation emitting semiconductor body, the first dopant is Mg and/or Zn and the second dopant is Te and/or Si.

According to at least one embodiment of the radiation emitting semiconductor body, the first dopant is Te and/or Si and the second dopant is Mg and/or Zn.

According to at least one embodiment of the radiation emitting semiconductor body, a thickness of the first intermediate region is at most 30 nm. The thickness extends, for example, in vertical direction. In particular, the thickness of the first intermediate region is at most 20 nm or 10 nm.

According to at least one embodiment of the radiation emitting semiconductor body, a thickness of the second intermediate region is at most 30 nm. The thickness extends, for example, in vertical direction. In particular, the thickness of the second intermediate region is at most 20 nm or 10 nm.

According to at least one embodiment of the radiation emitting semiconductor body, a thickness of the first intermediate region is at most 10 nm.

According to at least one embodiment of the radiation emitting semiconductor body, a thickness of the second intermediate region is at most 10 nm.

Due to such a thickness, the first semiconductor region and/or the second semiconductor region is positioned particularly close to the active region. Such a radiation emitting semiconductor body thus comprises particularly low charge carrier losses and efficient charge carrier injection into the active region.

According to at least one embodiment of the radiation emitting semiconductor body, a thickness of each of the barrier layers is equal to a thickness of the first intermediate layer.

For example, the first intermediate layer and the first blocking layer comprise the same thickness.

If the first intermediate layer and each of the barrier layers are of the same thickness, the first intermediate region is advantageously particularly easy to produce, as the intermediate region can be produced in the same way as the barrier layers.

According to at least one embodiment of the radiation emitting semiconductor body, a thickness of each of the barrier layers is greater than a thickness of the first intermediate layer.

If the barrier layers are each formed thicker than the first intermediate layer, the first intermediate region is particularly formed thin, which advantageously leads to particularly good charge carrier injection and low charge carrier losses.

According to at least one embodiment of the radiation emitting semiconductor body, a thickness of each of the barrier layers is equal to a thickness of the second intermediate layer.

According to at least one embodiment of the radiation emitting semiconductor body, a thickness of each of the barrier layers is greater than a thickness of the second intermediate layer.

Alternatively, a thickness of the barrier layers is smaller than a thickness of the first intermediate layer and/or the second intermediate layer. As a result, diffusion of the first dopant and/or the second dopant is particularly well inhibited advantageously.

According to at least one embodiment of the radiation emitting semiconductor body, the first intermediate region comprises at least two first blocking layers and at least two first intermediate layers arranged alternately above each other.

According to at least one embodiment of the radiation emitting semiconductor body, the second intermediate region comprises at least two second blocking layers and at least two second intermediate layers arranged alternately above each other.

Moreover, a laser diode is specified comprising a radiation emitting semiconductor body described herein. All features disclosed in connection with the radiation emitting semiconductor body are therefore also disclosed in connection with the laser diode and vice versa.

According to at least one embodiment, the laser diode comprises a resonator comprising a first end region and a second end region.

According to at least one embodiment, the active region is configured to generate electromagnetic radiation. For example, the radiation emitting semiconductor body extends in lateral directions between a first end face of the semiconductor body, which is arranged in the first end region, and a second end face of the semiconductor body, which is arranged in the second end region.

According to at least one embodiment of the semiconductor chip, the active region is arranged in the resonator.

For example, the edge-emitting laser diode is configured to emit electromagnetic laser radiation from a facet arranged in the first end region or arranged in the second end region.

For example, the facet is arranged in a plane that extends substantially in vertical direction. Extending substantially in vertical direction means that the plane is inclined to the vertical direction by at most 5°, in particular by at most 1°.

The electromagnetic laser radiation is, in particular, monochromatic and coherent laser light. The electromagnetic laser radiation is, for example, infrared, IR, radiation, visible radiation or ultraviolet, UV, radiation.

Moreover, a light emitting diode is specified comprising a radiation emitting semiconductor body described herein. All features disclosed in connection with the radiation emitting semiconductor body are therefore also disclosed in connection with the light emitting diode and vice versa.

According to at least one embodiment, the light emitting diode comprises a first contact layer and a second contact layer. The first contact layer and the second contact layer are configured to supply the radiation emitting semiconductor body with current.

The first contact layer and/or the second contact layer comprises an electrically conducting material. The first contact layer and/or the second contact layer comprises a metal, for example. Alternatively, the first contact layer and/or the second contact layer comprises a transparent conductive oxide (TCO).

According to at least one embodiment of the light emitting diode, the first contact layer is electrically conductively connected to the first semiconductor region.

According to at least one embodiment of the light emitting diode, the second contact layer is electrically conductively connected to the second semiconductor region.

### BRIEF DESCRIPTION OF THE DRAWINGS

In the following, the radiation emitting semiconductor body is explained in more detail with reference to the Figures using exemplary embodiments.

They show:
FIG. 1 a schematic sectional view of a radiation emitting semiconductor body according to an exemplary embodiment, and
FIGS. 2, 3, 4, 5, 6 and 7 schematic band gap diagrams of a radiation emitting semiconductor body according to one exemplary embodiment in each case.

### DETAILED DESCRIPTION

Elements that are identical, similar or have the same effect are marked with the same reference signs in the Figures. The Figures and the proportions of the elements shown in the Figures are not to be regarded as being to scale. Rather, individual elements can be shown in exaggerated size for better visualization and/or better comprehensibility.

The radiation emitting semiconductor body 1 according to the exemplary embodiment of FIG. 1 comprises a first semiconductor region 2 and a second semiconductor region 3.

An active region 4 and a first intermediate region 7 are arranged between the first semiconductor region 2 and the second semiconductor region 3.

The active region 4 is arranged on the second semiconductor region 3 and the first intermediate region 7 is arranged on the active region 4.

The second semiconductor region 3, the active region 4, the first intermediate region 7 and the first semiconductor region 2 are stacked above each other in vertical direction, in particular in the order indicated.

For example, the second semiconductor region 3, the active region 4, the first intermediate region 7 and the first semiconductor region 2 are grown epitaxially above each other. The vertical direction extends parallel to a growth direction x of the radiation emitting semiconductor body 1.

The active region 4 comprises two quantum well layers 5 and three barrier layers 6, which are arranged alternately above each other in vertical direction. Furthermore, the first intermediate region 7 comprises a first blocking layer 8 and a first intermediate layer 9, which are also arranged above each other in vertical direction.

The first blocking layer 8 and the first semiconductor region 2 comprise the first material composition. The first intermediate layer 9 and the barrier layers 6 comprise the third material composition.

The first semiconductor region 2 additionally comprises a first dopant. That is, the first dopant is added to the first material composition. For example, the first dopant is Mg. Thus, a first doping type of the first semiconductor region 2 is a p-type. Furthermore, a second doping type of the second semiconductor region 3 is an n-type.

Furthermore, the first semiconductor region 2 comprises a first semiconductor layer 13 of the first doping type, which is directly adjacent to the first intermediate layer 9 of the first intermediate region 7. The second semiconductor region 3 comprises a second semiconductor layer 14 of the second doping type, which is directly adjacent to the active region 4.

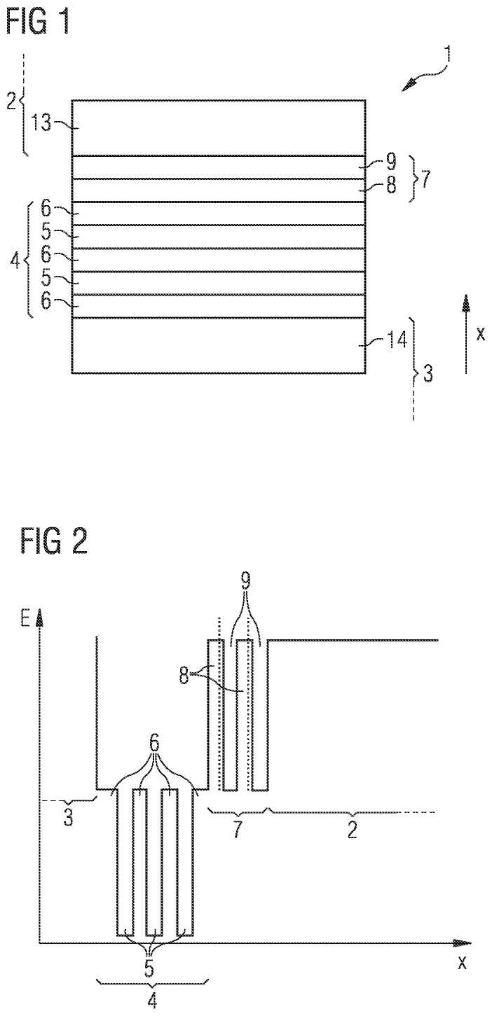

In the diagrams according to FIGS. 2, 3 and 4, energies of band gaps of layers of the radiation emitting semiconductor body 1 described herein are shown schematically. The energy of the band gap is provided in arbitrary units on the y-axis.

The x-axis represents a thickness of the layers in growth direction x, also provided in arbitrary units.

The radiation emitting semiconductor body 1 described here comprises InₓGa_{y}Al₁₋ₓP, where 0≤x≤1 and 0≤y≤1. The band gap of the first semiconductor region 2, the second semiconductor region 3, the active region 4 and the first intermediate region 7 is predeterminable by means of an aluminum concentration.

The diagram according to FIG. 2 is representative of a radiation emitting semiconductor body 1 comprising a first intermediate region 7, wherein the first intermediate region 7 comprises two first blocking layers 8 and two first intermediate layers 9. Furthermore, an active region 4 of the radiation emitting semiconductor body 1 comprises three quantum well layers and four barrier layers 6. As in FIG. 1, the first intermediate region 7 is arranged between the first semiconductor region 2 and the active region 4. The first semiconductor region 2 comprises first dopants, such as Mg.

The first blocking layers 8 comprise an aluminum concentration that is equal to an aluminum concentration of the first semiconductor region 2. The first intermediate layers 9 comprise an aluminum concentration that is equal to an aluminum concentration of the barrier layers 6. Thus, a band gap of the first blocking layers 8 is equal to a band gap of the first semiconductor region 2. Furthermore, a band gap of the first intermediate layers 9 is equal to a band gap of the barrier layers 6.

For example, during epitaxial growth of the first intermediate region 7, the first of the first blocking layers 8 is grown first, followed by the first of the first intermediate layers 9. In the case of such a growth, a region between the first blocking layers 8 and the first intermediate layer 9, which is marked with dashed lines in

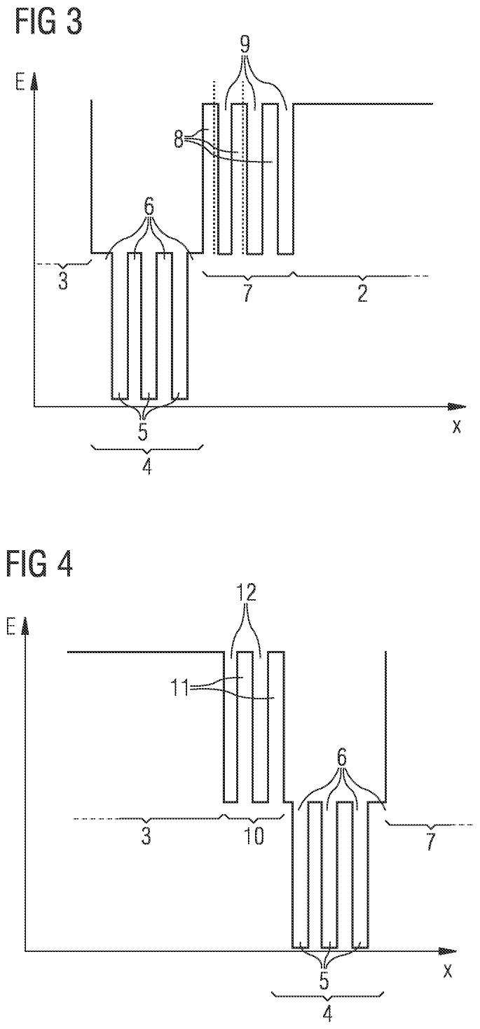

FIGS. 2 and 3, comprises the property that diffusing atoms of the first dopant, which move from the first semiconductor region 2 towards the active region 4, are hindered in their further diffusion by the first intermediate region 7. Due to such a first intermediate region 7, the active region 4 is advantageously free of first dopants.

The diagram according to FIG. 3 is representative of a radiation emitting semiconductor body 1 comprising a first intermediate region 7, wherein the first intermediate region 7 comprises three first blocking layers 8 and three first intermediate layers 9. Thus, in contrast to the radiation emitting semiconductor body 1 according to FIG. 2, even more diffusing atoms of the first dopant can be prevented from diffusing by the formed interfaces.

The diagram according to FIG. 4 is representative of a radiation emitting semiconductor body 1 which, in addition to the first intermediate region 7, comprises a second intermediate region 10. The second intermediate region 10 is arranged between a second semiconductor region 3 and the active region 4. The second intermediate region 10 comprises two second blocking layers 11 and two second intermediate layers 12.

The second semiconductor region 3 comprises second dopants, such as Te. Interfaces are also formed between directly adjacent second blocking layers 11 and second intermediate layers 12 during epitaxial growth.

The atoms of the second dopant diffusing through the second intermediate region 10, which diffuse from the second semiconductor region 3 to the active region 4, are also prevented from diffusing further in direction of the active region 4 by the interface. Due to such a first intermediate region 7, the active region 4 is advantageously free of second dopants.

In contrast to FIG. 2, the first blocking layers 8 comprise a fourth material composition and the first intermediate layers 9 comprise a fifth material composition.

The fourth material composition comprises an aluminum concentration that is smaller than an aluminum concentration of the first material composition. In other words, a band gap of the first blocking layers 8 is in each case smaller than a band gap of the first semiconductor region. For example, the band gap of the first blocking layers 8 is in each case at most 5%, in particular at most 10% or 30%, smaller than the band gap of the first semiconductor region, in particular of the first semiconductor layer.

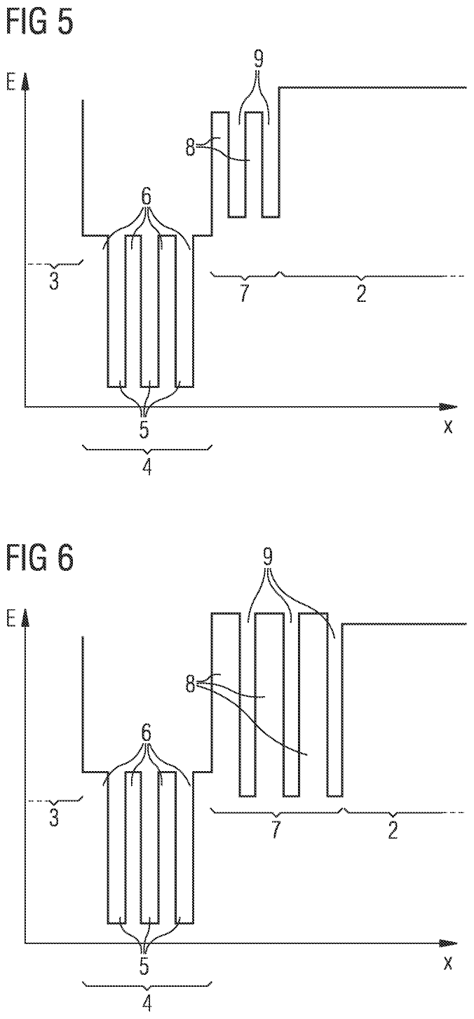

The fifth material composition comprises an aluminum concentration that is greater than an aluminum concentration of the third material composition. This means that a band gap of the first intermediate layers 9 is in each case greater than a band gap of the barrier layers 6. For example, the band gap of the first intermediate layers 9 is in each case greater than the band gap of the barrier layers 6 by at most 5%, in particular by at most 10% or 30%. 5 In contrast to FIG. 5, the fourth material composition according to FIG. 6 comprises an aluminum concentration that is greater than an aluminum concentration of the first material composition. This means that a band gap of the first blocking layers 8 is in each case larger than a band gap of 10 the first semiconductor region. For example, the band gap of the first blocking layers 8 is in each case greater than the band gap of the first semiconductor region, in particular the first semiconductor layer, by at most 5%, in particular by at most 10% or 30%.

Furthermore, the fifth material composition according to FIG. 6 comprises an aluminum concentration that is smaller than an aluminum concentration of the third material composition. That is, a band gap of the first intermediate 20 layers 9 is in each case smaller than a band gap of the barrier layers 6. For example, the band gap of the first intermediate layers 9 is in each case at most 5%, in particular at most 10% or 30%, smaller than the band gap of the barrier layers 6.

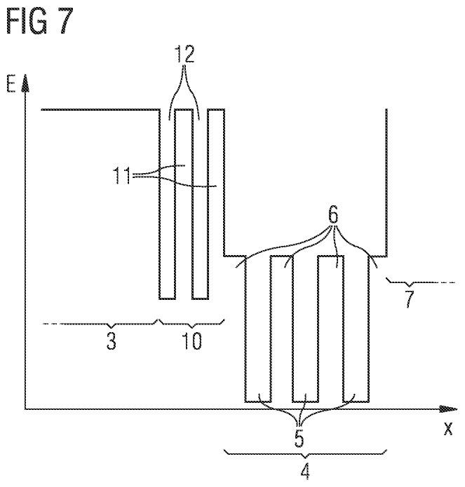

In contrast to FIG. 4, the second blocking layers 11 according to FIG. 7 comprise a sixth material composition and the second intermediate layers 12 comprise a seventh material composition.

The sixth material composition comprises an aluminum concentration equal to the second material composition as shown in FIG. 4.

The seventh material composition comprises an aluminum concentration that is smaller than an aluminum concentration of the third material composition. That is, a band gap of the second intermediate layers 12 is greater in each case than a band gap of the barrier layers 6. For example, the band gap of the second intermediate layers 12 is greater in each case by at most 5%, in particular by at most 10% or 30%, than the band gap of the barrier layers 6.

The features and exemplary embodiments described in connection with the Figures can be combined with one another in accordance with further exemplary embodiments, even if not all combinations are explicitly described. Furthermore, the exemplary embodiments described in connection with the Figures can alternatively or additionally comprise further features as described in the general part.

The invention is not limited to the exemplary embodiments by the description thereof. Rather, the invention includes any new feature as well as any combination of features, which includes in particular any combination of features in the patent claims, even if this feature or combination itself is not explicitly stated in the patent claims or exemplary embodiments.

1. A radiation emitting semiconductor body comprising:
a first semiconductor region of a first doping type comprising a first material composition,
a second semiconductor region of a second doping type comprising a second material composition,
an active region arranged between the first semiconductor region and the second semiconductor region,
a first intermediate region arranged between the first semiconductor region and the active region, and
a second intermediate region arranged between the second semiconductor region and the active region, wherein
the active region comprises a plurality of quantum well layers and a plurality of barrier layers which are arranged alternately above each other,
the barrier layers comprise a third material composition,
the first intermediate region comprises at least one first blocking layer and at least one first intermediate layer,
the first blocking layer comprises a fourth material composition and the first intermediate layer comprises a fifth material composition,
the second intermediate region comprises at least one second blocking layer and at least one second intermediate layer,
the second blocking layer comprises a sixth material composition and the second intermediate layer comprises a seventh material composition,
all material compositions are based on AlGaInP, and
a thickness of the first intermediate region is at most 30 nm.

2. The radiation emitting semiconductor body according to claim 1, in which the fourth material composition is the same as the first material composition.

3. The radiation emitting semiconductor body according to claim 1, in which the fifth material composition is the same as the third material composition.

4. (canceled)

5. The radiation emitting semiconductor body according to claim 4, in which
the sixth material composition is the same as the second material composition, and/or
the seventh material composition is the same as the third material composition.

6. The radiation emitting semiconductor body according to claims 1, wherein
the first semiconductor region comprises a first dopant, and
the second semiconductor region comprises a second dopant.

7. The radiation emitting semiconductor body according to claim 6, in which
the first dopant is Mg and/or Zn and the second dopant is Te and/or Si, or
the first dopant is Te and/or Si and the second dopant is Mg and/or Zn.

8. The radiation emitting semiconductor body according to claim 1, in which a thickness of the second intermediate region is at most 30 nm.

9. The radiation emitting semiconductor body according to claim 1, in which a thickness of the first intermediate region is at most 10 nm.

10. The radiation emitting semiconductor body according to claim 1, in which a thickness of the second intermediate region is at most 10 nm.

11. The radiation emitting semiconductor body according to claim 1, in which a thickness of each of the barrier layers is greater than a thickness of the second intermediate layer .

12. The radiation emitting semiconductor body according to claims 1, in which the first intermediate region comprises at least two first blocking layers and at least two first intermediate layers which are arranged alternately above each other.

13. The radiation emitting semiconductor body according to claim 1, in which the second intermediate region comprises at least two second blocking layers and at least two second intermediate layers which are arranged alternately above each other.

14. A laser diode, comprising: with,
a radiation emitting semiconductor body according to claim 1, and
a resonator comprising a first end region and a second end region, wherein
the active region is configured to generate electromagnetic radiation, and
the active region is formed in the resonator.

15. A light emitting diode, comprising:
a radiation emitting semiconductor body according to claim 1,
a first contact layer, and
a second contact layer, wherein
the first contact layer is electrically conductively connected to the first semiconductor region, and
the second contact layer is electrically conductively connected to the second semiconductor region.
